(19) United States
(12) Patent Application Publication
(10) Pub. No.: US 2022/0205085 A1
(43) Pub. Date: Jun. 30, 2022

(54) DEPOSITION PROCESS USING ADDITIONAL CHLORIDE-BASED PRECURSORS

(71) Applicant: Aledia, Grenoble (FR)

(72) Inventors: Olga Kryliouk, Fort Myers, FL (US); Jerome Napierala, Saint Egrève (FR)

(73) Assignee: Aledia, Grenoble (FR)

(21) Appl. No.: 17/606,193

(22) PCT Filed: Apr. 23, 2020
(86) PCT No.: PCT/US2020/029520

§ 371 Date: Oct. 25, 2021

Related U.S. Application Data
(60) Provisional application No. 62/838,809, filed on Apr. 25, 2019.

(51) Int. Cl. C23C 16/30; C23C 16/448; C30B 25/02; C30B 29/40; H01L 21/02

(52) U.S. Cl. CPC C23C 16/303; C23C 16/4488; H01L 21/0262; C30B 29/403; H01L 21/0254; C30B 25/02

(57) ABSTRACT

Deposition methods using Cl-based precursors to produce III-nitride materials are generally described.

### TECHNICAL FIELD

Deposition methods using chloride (Cl)-based precursors to produce III-nitride materials that contain a high concentration of Group-III elements, such as indium (In) and aluminum (Al), are generally described.

### BACKGROUND

Chemical deposition processes are used to deposit layers (e.g., thin films) that can be used, for example, in semiconductor devices. Conventional chemical vapor deposition (CVD) processes may utilize a wide array of precursors, including single metals. Metal-organic chemical vapor deposition (MOCVD), a subset of CVD, may utilize metal-organic species as precursors. Additionally, hydride vapor phase epitaxy (HVPE) may utilize chloride (Cl)-based sources as a precursor, in addition to single metals. MOCVD, and HVPE processes are generally known in the art and are often used for the deposition of III-nitride materials.

The structural and compositional integrity of III-nitride materials (e.g., InGaN) can be improved by employing a high concentration of certain Group-III elements (e.g., In) into a deposited III-nitride material layer. Such III-nitride materials may be used as efficient semiconductors in optoelectronics and electronic applications. However, the efficiency of III-nitride materials degrades sharply in correlation with an increasing content of certain Group-III elements (e.g., In), as InN-containing materials have a high equilibrium vapor pressure as compared to GaN-containing materials or AlN-containing materials.

Accordingly, improved methods are needed for the deposition of III-nitride materials comprising a high concentration of Group-III elements.

### SUMMARY

Deposition methods using Cl-based precursors to produce III-nitride materials are generally described.

In some embodiments, a deposition method is described, wherein the method comprises providing a Group-III precursor, providing a first Cl-based precursor in the presence of the Group-III precursor to produce a first intermediate species, providing a second Cl-based precursor in the presence of the first intermediate species to produce a second intermediate species, providing a N-based precursor in the presence of the second intermediate species to produce a product, and depositing a layer comprising a III-nitride material onto a surface of a substrate.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1 shows a schematic representation of the series of steps involved in a deposition method, according to certain embodiments;

FIG. 2 shows a schematic diagram of the deposition method, according to some embodiments; and

FIG. 3 shows a non-limiting temperature growth map of the morphological evolution of a deposition layer as a result of using an additional Cl-based precursor.

### DETAILED DESCRIPTION

Methods related to the deposition of III-nitride materials are provided. In some embodiments, the deposition method includes the use of an additional Cl-based precursor, in addition to a conventional first Cl-based precursor, Group-III precursor, and/or a N-based precursor. The use of Cl-based precursors during the deposition process has significant advantages over conventional deposition methods. For example, the methods described herein can result in the stoichiometric formation of clean intermediate species with little to no byproducts formed during the deposition process. Resultantly, the deposition methods may be used to provide a high-quality material. For example, in some aspects, there may be little to no defects and/or contaminants in the deposited III-nitride material. The methods described herein are particularly advantageous for the production of crystalline III-nitride materials with a high content (e.g., between greater than or equal to 20 wt. % and less than 100 wt. %) of certain Group-III elements, such as In.

The deposition method may comprise reacting a Group-III precursor with a Cl-based precursor to produce a first intermediate species, which may subsequently react with an additional Cl-based precursor to produce a second intermediate species. The second intermediate species, in some embodiments, may react with a N-based precursor, thereby producing a product comprising a Group-III nitride material. In some aspects, the product resulting from the use of Cl-based precursors during the deposition process may nucleate and oligomerize to produce high quality III-nitride materials by one-dimensional, two-dimensional, and/or three-dimensional growth. Such III-nitride materials may be useful for implementation in semiconductor devices such as light-emitting diodes.

Methods related to the deposition of layers (e.g., thin-films) are described herein. According to certain embodiments, methods related to depositing layers may generally comprise a series of standard initial steps. In certain embodiments, for example, the deposition method may initially comprise providing a substrate and arranging the substrate in an evacuable chamber and/or reactor. In some aspects, the method may further comprise reducing the pressure of the chamber and/or reactor (e.g., to less than or equal to 50 torr), such as in the case of MOCVD. In certain embodiments, the deposition method may comprise an optional step of heating the substrate to cause desorption of contaminants from the growth surface, followed by adjusting the substrate temperature to that desired for growth of the layer, which may take place after arranging the substrate in the chamber and/or reactor.

In certain embodiments, the deposition method may be related to HVPE. The method of HVPE may utilize one or more single metal precursors. In some embodiments related to HVPE, the deposition method may be performed at atmospheric pressure (e.g., at 760 torr). Methods related to HVPE may be advantageous when compared to other deposition techniques, because HVPE has a high throughput (e.g., high deposition rate) and low operation cost. Additionally, HVPE may be advantageous because deposition may be performed at thermodynamic equilibrium.

In some embodiments, the deposition method may be related to MOCVD. In some aspects, the method of MOCVD may utilize a metal-organic precursor species. In certain embodiments related to MOCVD, the method may be performed under suitable vacuum conditions (e.g., the vacuum may have a pressure of less than or equal to 50 ton). Methods related to MOCVD may be advantageous when compared to other deposition techniques because MOCVD has a high throughput (e.g., high deposition rate), high reproducibility, and low operation cost. According to some embodiments, the techniques described herein are particularly well-suited for MOCVD processes.

In certain embodiments, the method of HVPE and/or MOCVD further comprise providing two or more precursor source materials at one or more specified flow rates into the chamber and/or reactor and directing the two or more precursor source materials towards the substrate. In some aspects, the flow rate of the two or more precursor source materials may range from 1 standard cubic centimeter per minute (sccm) to 500 sccm, depending on the composition of the precursor source material. In some embodiments, one or more diluent inert gases (e.g., Ar and/or N₂) may be used to provide the two or more precursor source materials into the chamber and/or reactor. In some embodiments, one or more precursor materials may be provided as a gas. In some other aspects, one or more precursor material may be provided as a solid and/or a liquid. which are evaporated and/or vaporized into the gas phase by heating the one or more precursor materials (e.g., to between 500° C. and 1000° C.) and/or reducing the pressure of a chamber and/or reactor initially containing the precursor source materials. According to some embodiments, the precursor source materials may react in the gas phase in the atmosphere of the chamber and/or reactor to form, for example, a product comprising a gas phase aggregate. In certain embodiments, the product desorbs from the gas phase onto a surface of the substrate. In some embodiments, a catalyst and/or initiator may be used in order to facilitate a chemical reaction between the two or more precursor source materials.

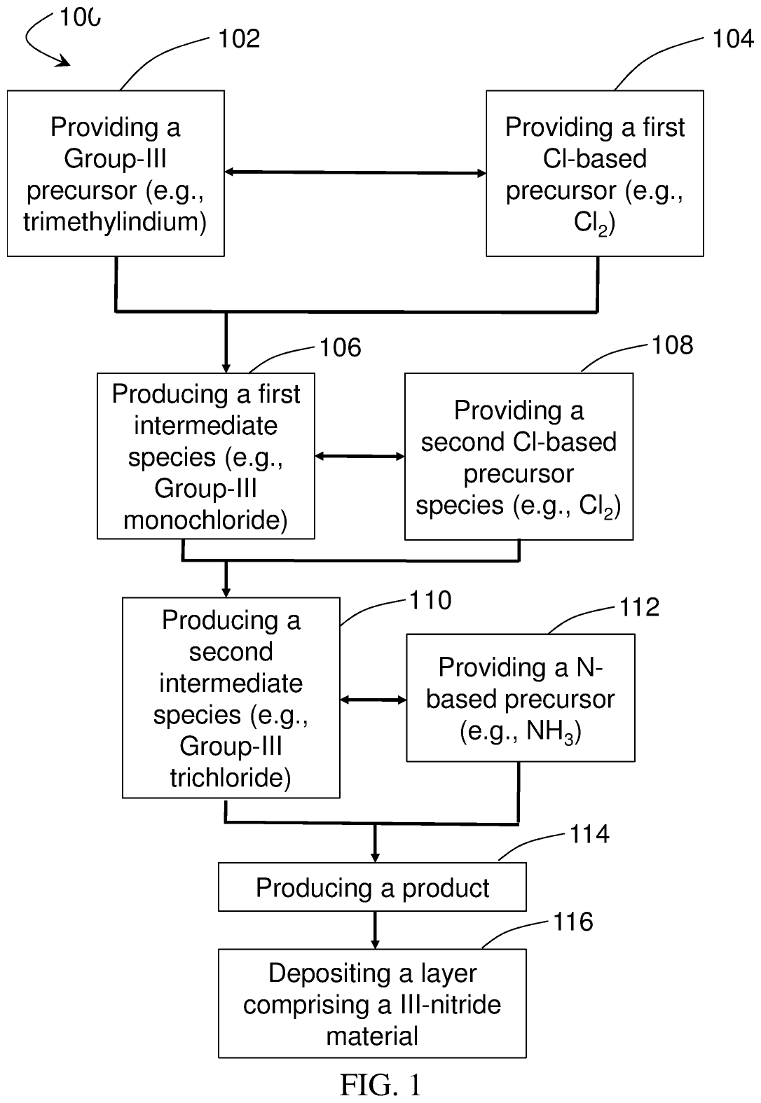

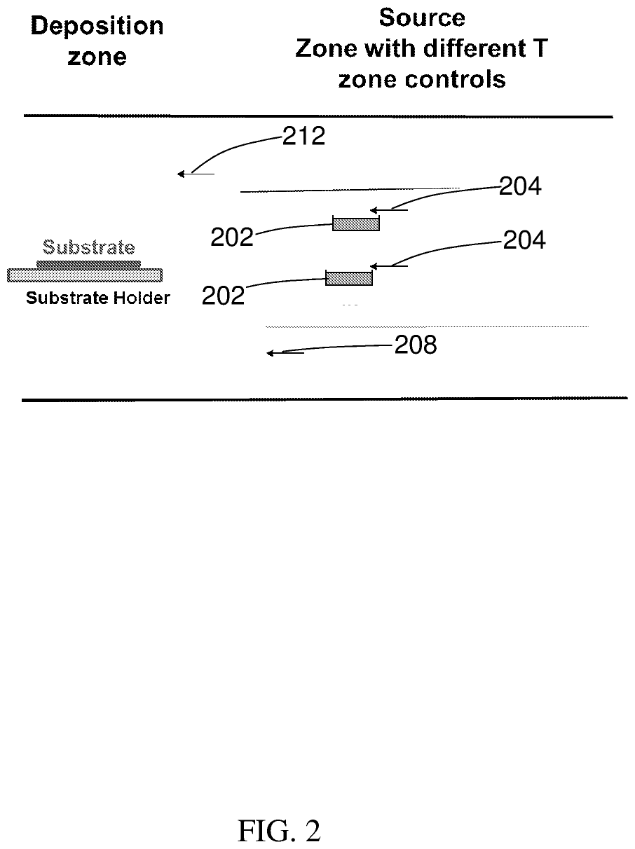

In certain embodiments, a typical HVPE and/or MOCVD system may include one or more sources of and feed lines for gases, mass flow controllers for metering the gases into the system, a chamber and/or reactor, a system for heating the substrate on which the layer (e.g., thin film) is to be deposited, and temperature sensor to control and/or regulate the temperature of the system. In some embodiments, the method comprises providing a Group-III precursor. As explained above, the Group-III precursor may be provided as a solid, the Group-III precursor may be provided as a solid that is evaporated and/or vaporized into a gas, or the Group-III precursor may be provided as a gas. FIG. 1 shows a schematic representation of the series of steps involved in a deposition method, according to certain embodiments. As shown in FIG. 1, deposition method 100 comprises step 102 comprising providing a Group-III precursor. In certain embodiments, the Group-III precursor comprises indium, gallium, aluminum, trimethylindium, trimethylgallium, triethylgallium, trimethylaluminum, and/or mixtures thereof. In some MOCVD processes, the Group-III precursor may be trimethylindium, trimethylgallium, trimethylgallium, trimethylaluminum, and/or mixtures thereof. In certain HVPE processes, the Group-III precursor may be indium, gallium, aluminum, and/or mixtures thereof. In certain embodiments wherein trimethylindium, trimethylgallium, and/or trimethylaluminum is the Group-III precursor species, the trimethyl-metal precursor may decompose (e.g., thermally decompose) into the respective dimethyl-metal species and subsequent monomethyl-metal species upon exposure to temperatures that induce evaporation and/or vaporization. For example, in a non-limiting embodiment, elevated temperatures may thermally decompose trimethylindium into dimethylindium, which may further thermally decompose into monomethylindium. FIG. 2 shows a schematic diagram of the deposition method, according to some embodiments. As shown in FIG. 2, one or more Group-III precursors 202 may be provided as a solid.

In certain embodiments, the method comprises providing a first Cl-based precursor (e.g., in the gas phase). Step 104 of deposition method 100, for example, comprises providing a first Cl-based precursor. The first Cl-based precursor may be provided in the presence of the Group-III precursor. In certain embodiments, step 104 of deposition method 100 may take place before, after, and/or during step 102. According to some embodiments, the first Cl-based precursor may comprise Cl₂, HCl, and/or mixtures thereof. As shown in FIG. 2, first Cl-based precursor 204 may be flowed over one or more Group-III precursors 202 that has been provided as a solid.

According to certain embodiments, providing the first Cl-based precursor in the presence of the Group-III precursor may produce a first intermediate species. For example, step 106 of deposition method 100 comprises producing a first intermediate species. In certain embodiments, the first intermediate species may be the product of a gas phase chemical reaction between the Group-III precursor and the first Cl-based precursor. In some embodiments, the first intermediate species may comprise a Group-III monochloride, or a mixture of Group-III monochlorides. In a non-limiting embodiment, for example, the thermal decomposition product of the Group-III precursor (e.g., monomethylindium) may react with the first Cl-based precursor (e.g., HCl), thereby producing a Group-III monochloride and volatile methane gas byproduct. In certain embodiments, the Group-III monochloride may comprise InCl, GaCl, AlCl, dimers thereof, and/or mixtures thereof. Other Group-III monochlorides are also possible.

In some embodiments, the method comprises providing a second Cl-based precursor (e.g., in the gas phase). In some embodiments, the second Cl-based precursor may be provided in the presence of the Group-III precursor, the first Cl-based precursor, and/or the first intermediate species (e.g., the Group-III monochloride). For example, step 108 of deposition method 100 comprises providing a second Cl-based precursor species. In certain embodiments, step 108 may take place after step 106 (e.g., after the first intermediate species is produced). In certain aspects, step 108 may take place before and/or during step 106 (e.g., before the first intermediate species is produced and/or while the first intermediate species is produced). According to certain embodiments, the second Cl-based precursor is Cl₂, HCl, and/or mixtures thereof. As shown in FIG. 2, second Cl-based precursor 208 may be provided.

In certain embodiments, the first Cl-based precursor and the second Cl-based precursor are the same. In some other embodiments, the first Cl-based precursor and the second Cl-based precursor are different (e.g., the first Cl-based precursor is HCl and the second Cl-based precursor is Cl₂, or vice versa).

According to some embodiments, providing the second Cl-based precursor in the presence of the first intermediate species produces a second intermediate species. For example, step 110 of deposition method 100 comprises producing a second intermediate species. In some embodiments, the second intermediate species may be the product of a gas phase chemical reaction between the first intermediate species and the second Cl-based precursor. According to certain embodiments, the second intermediate species is a Group-III trichloride, or a mixture of Group-III trichlorides. In a non-limiting embodiment, for example, the first intermediate product (e.g., InCl) may react with the second Cl-based precursor (e.g., Cl₂), thereby producing the Group-III trichloride. In certain embodiments, the Group-III trichloride may comprise InCl₃, GaCl₃, AlCl₃, dimers thereof, and/or mixtures thereof. Other Group-III trichlorides are also possible.

According to some embodiments, the first intermediate species and the second intermediate species may both be produced at the same time. For example, the Group-III precursor and the first Cl-based precursor may react to produce the first intermediate species. The first intermediate species may then react with the second Cl-based precursor to provide the second intermediate species while the Group-III precursor and the Cl-based precursor are still reacting to product the first intermediate species. Accordingly, in certain aspects, the first intermediate species may be the dominant species in the vapor phase.

In certain embodiments, the method comprises providing a N-based precursor (e.g., in the gas phase). In some aspects, the N-based precursor may be provided in the presence of the second intermediate species, second Cl-based precursor, first intermediate species, first Cl-based precursor, and/or Group-III precursor. For example, step 112 of deposition method 110 comprises providing a N-based precursor. In certain embodiments, step 112 may take place after step 110 (e.g., after the second intermediate species is produced). In certain aspects, step 112 may take place before and/or during step 110 (e.g., before the second intermediate species is produced and/or while the second intermediate species is produced). According to some embodiments, the N-based precursor may comprise ammonia (NH₃). As shown in FIG. 2, N-based precursor 212 may be provided.

According to certain embodiments, providing the N-based precursor (e.g., in the presence of the second intermediate species) produces a product. Step 114 of deposition method 110, for example, comprises producing a product. In some embodiments, the product may be the product of a gas phase chemical reaction between the second intermediate species and the N-based precursor.

In certain embodiments, the product may comprise a Group-III amidodichloride, or a mixture of Group-III amidodichlorides. In a non-limiting embodiment, for example, the second intermediate species (e.g., InCl₃) may react with the N-based precursor (e.g., NH₃), thereby producing a Group-III amidodichloride and volatile HCl byproduct. In certain embodiments, upon formation, the Group-III amidodichloride may oligomerize. The oligomerization of the Group-III amidodichloride, in some aspects, may result in the nucleation (e.g., scattered nucleation of Group-III amidodichloride nanoparticles) and/or the growth of a one-dimensional, two-dimensional, and/or three-dimensional product. The growth of the one-dimensional, two-dimensional, and/or three-dimensional product may take place in the gas phase (e.g., in the atmosphere of the chamber and/or reactor) and/or on the surface of the substrate. In some embodiments, the Group-III amidodichloride may comprise Cl₂InNH₂, Cl₂GaNH₂, Cl₂AlNH₂, oligomers thereof (e.g., [Cl₂InNH₂]ₙ, [Cl₂GaNH₂]ₙ, and/or [Cl₂AlNH₂]ₙ), and/or mixtures thereof. Other Group-III amidodichlorides are also possible. According to some embodiments, the Group-III amidodichloride and/or oligomer thereof may readily react to produce a III-nitride material (e.g., by loss of two equivalents of HCl per monomer).

In certain embodiments, the method comprises depositing a layer comprising the III-nitride material onto a surface of a substrate. For example, step 116 of method 100 comprises depositing a layer comprising the III-nitride material. In certain embodiments, the III-nitride material may be any of a variety of suitable III-nitride materials. For example, in certain embodiments, the III-nitride material may be a binary III-nitride material (e.g., InN), a ternary III-nitride material (e.g., InGaN), or a quaternary III-nitride material (e.g., AlGaInN). In some embodiments, the III-nitride material may comprise GaN, AlN, InN, AlGaN, InGaN, AlGaInN, and/or mixtures thereof.

In certain embodiments, the layer comprising the III-nitride material may be an epitaxial layer. The layer (e.g., the III-nitride epitaxial layer) may, in some embodiments, have a wide bandgap range. For example, the III-nitride epitaxial layer may have a bandgap range from 0.7 eV (e.g., InN) to 6.2 eV (e.g., AlN).

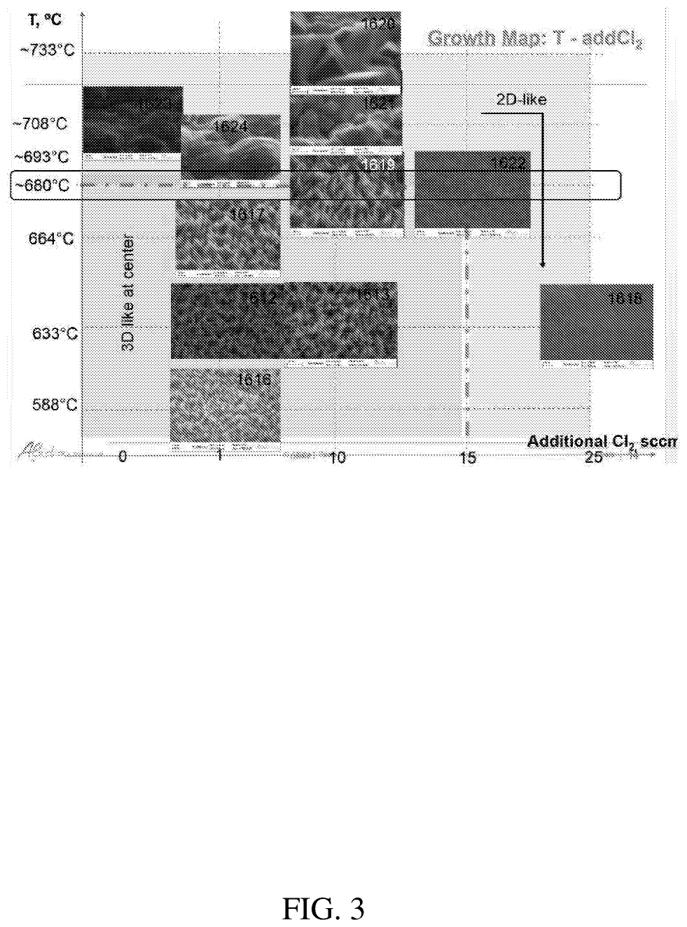

In some embodiments, the layer (e.g., the III-nitride material epitaxial layer) is deposited in the form of a planar layer. In other embodiments, the layer is deposited in a non-planar form. The GaN-based material layer may comprise a one-dimensional, two-dimensional, or three-dimensional structure. For example, the layer may be deposited as a shell (or other configuration) or a wire structure (e.g., a nanowire). In certain embodiments, the layer may be deposited as plurality of nanowires and/or nanorods with lengths ranging from 500 to 1,200 nm and/or diameters ranging from 50 to 300 nm. The form of the deposited layer may depend on the substrate configuration, as described further below, and/or the intended application of the resulting semiconductor device. FIG. 3 shows a non-limiting temperature growth map of the morphological evolution of a deposition layer as a result of using an additional Cl-based precursor. In reference to FIG. 3, the growth of the deposition layer between a temperature of 588° C. and 680° C. and/or at a flow rate of the second Cl-based precursor of between greater than 0 sccm and 15 sccm may provide a two-dimensional layer of various thicknesses, as is described herein in greater detail. Also in reference to FIG. 3, the growth of the deposition layer between a temperature of 588° C. and 680° C. and/or at a flow rate of the second Cl-based precursor of between greater than 0 sccm and 15 sccm may provide a one-dimensional layer and/or three-dimensional layer comprising nanostructures, such as nanowires and/or nanorods. In certain embodiments, altering the temperature and additional Cl-based precursor conditions (e.g., the flow rate of the second Cl-based precursor) may provide one-dimensional, two-dimensional, and/or three-dimensional layers.

According to certain embodiments, the methods described herein are particularly useful for the incorporation of high amounts of certain Group-III elements, such as In, into the III-nitride material. In certain embodiments, the III-nitride material may comprise greater than or equal to 10 wt. % In, greater than or equal to 20 wt. % In, greater than or equal to 30 wt. % In, greater than or equal to 40 wt. % In, greater than 50 wt. % In, greater than or equal to 60 wt. % In, greater than or equal to 70 wt. % In, greater than or equal to 80 wt. % In, or greater than or equal to 90 wt. % In. In certain embodiments, the III-nitride material may comprise less than 100 wt. % In, less than or equal to 90 wt. % In, less than or equal to 80 wt. % In, less than or equal to 70 wt. % In, less than or equal to 60 wt. % In, less than or equal to 50 wt. % In, less than or equal to 40 wt. % In, less than or equal to 30 wt. % In, or less than or equal to 20 wt. % In. Combinations of the above recited ranges may also be possible (e.g., the III-nitride material comprises greater than or equal to 20 wt. % In and less than or equal to 50 wt. % In). For example, in a non-limiting embodiment, the III-nitride material comprises In_{0.36}Ga_{0.64}N. The incorporation of high amounts of other certain Group-III elements is also possible, such as Ga and/or Al, in the same amounts recited above. The amount of certain Group-III elements, such as In, Ga, and/or Al, may be measured experimentally by spectroscopic methods such as X-ray photoelectron spectroscopy (XPS), X-ray powder diffraction (XRD), energy-dispersive X-ray spectroscopy (EDS), scanning electron microscopy (SEM), and/or transmission electron microscopy (TEM).

According to certain embodiments, the layer (e.g., the III-nitride material epitaxial layer) may have any of a variety of suitable thicknesses. For example, the layer may be a thickness of greater than or equal to 10 Å, greater than or equal to 1,000 Å, greater than or equal to 10,000 Å, greater than or equal to 50,000 Å, greater than or equal to 75,000 Å, and the like. In certain embodiments, the layer may have a thickness of less than or equal to 100,000 Å. Combinations of the above recited ranges are also possible (e.g., the layer has a thickness of greater than or equal to 1,000 Å and less than or equal to 100,000 Å). The thickness of the layer can be measured, in some embodiments, using experimental methods such as SEM and/or TEM.

According to certain embodiments, the deposition layer may have a relatively high internal quantum efficiency (IQE). The IQE of the deposition layer may be any of a variety of suitable values. IQE, as used herein, may be generally understood by one of ordinary skill in the art as the ratio of the number of charge carriers (e.g., electrons) collected by (e.g., injected into) the deposition layer to the number of photons of a given energy that are produced by the deposition layer. The IQE is dependent on emission wavelength, which, according to certain embodiments, may range between 400 nm and 700 nm. In some embodiments, the IQE of the deposition layer may be significantly improved relative to a layer that is deposited without using the methods described herein. For example, in certain embodiments, the IQE of the deposition layer may be at least two times greater, three times greater, four times greater, five times greater, or ten times greater than the IQE of a layer deposited without using the methods described herein.

In some embodiments, for an emission wavelength between 400 nm and 700 nm, the deposition layer has an IQE of greater than about 20%, greater than about 25%, greater than about 30%, greater than about 35%, greater than about 40%, greater than or equal to about 45%, or greater than 50%. In certain embodiments, for an emission wavelength between 400 nm and 700 nm, the deposition layer has an IQE of less than or equal to 55%, less than or equal to about 50%, less than or equal to about 45%, less than or equal to about 40%, less than or equal to about 35%, less than or equal to about 30%, or less than or equal to about 25%.

In a certain non-limiting embodiment, a deposition layer comprising bulk InGaN has an IQE of 36% for an emission wavelength of 575 nm. In a non-limiting embodiment, a deposition layer comprising bulk InGaN has an IQE of 38% for an emission wavelength of 675 nm. In a non-limiting aspect, a deposition layer comprising bulk InGaN has an IQE of 30% for an emission wavelength of 685 nm.

The IQE may be determined, in certain embodiments, using conventional spectrometers comprising a tunable light source (e.g., deuterium, quartz-tungsten-halogen (QTH), and/or xenon (Xe)), a detector (e.g., a photodetector), and additional components for beam manipulation and delivery. In some embodiments, the IQE is determined using photoluminescence techniques at room temperature or below room temperature.

According to certain embodiments, the deposition layer may have improved properties as compared to a layer that is deposited without using the methods described herein. For example, in certain embodiments, the deposition layer may have improved structural, physical (e.g., crystallinity), electronic, and/or optical properties. In certain embodiments, the improved structural, physical, electronic, and/or optical properties are a result of an increased amount of a Group-III element (e.g., In) that is incorporated into the deposition layer as a result of the methods described herein. For example, in some embodiments, the deposition layer is substantially crystalline throughout the bulk of the deposition layer. In certain embodiments, the improved structural, physical, electronic, and/or optical properties can be measured experimentally (e.g., using SEM, TEM, XPS, and the like).

In certain embodiments, the deposition layer may comprise less impurities as compared to a layer deposited without using the methods described herein. For example, in certain embodiments, the deposition layer may comprise less than or equal to about 2 wt. % impurities, less than or equal to about 1 wt. % impurities, or less than or equal to about 0.5 wt. % impurities. In certain embodiments, the deposition layer may comprise essentially no impurities. In some embodiments, the lack of or low level of impurities in the deposition layer may be a result of the clean and/or stoichiometric formation of the intermediate species (e.g., the first intermediate species and/or the second intermediate species) during the deposition method, with little to no formation of byproducts and/or contaminants in the III-nitride material. According to some embodiments, the lack of or low level of impurities in the deposition layer may be a result of a catalyst and/or initiator-free deposition method. In some embodiments, the deposition layer may display no yellow luminescence due to the lack of or low level of impurities in the deposition layer. In certain embodiments, the impurities of the deposition layer may be evaluated experimentally (e.g., using SEM, TEM, X-ray spectroscopy, and the like).

In a non-limiting embodiment, the methods described herein resulted in the production of a III-nitride material comprising InGaN (e.g., In_{0.36}Ga_{0.64}N) comprising essentially no impurities.

As noted above, the methods described herein involve depositing a III-nitride material layer on a substrate. According to some embodiments, the substrate may be any of a variety of suitable substrates. For example, in certain embodiments, the substrate may comprise conventional substrate materials such as metal oxide (e.g., an aluminum oxide such as sapphire, zinc oxide, and/or magnesium oxide) or silicon (e.g., elemental silicon, silicon dioxide, and/or silicon carbide). It should be understood that the substrate may also include any number of layers deposited thereon (i.e., prior to the deposition of the III-nitride material layer described herein). For example, the substrate may include one or more additional III-nitride material-based layers deposited on a surface of the above-noted substrate materials (e.g., SiC, Si, sapphire).

As noted above, the substrate may have a variety of suitable forms. For example, the substrate may have a planar configuration. In some embodiments, the substrate may have a non-planar configuration such as a wire (e.g., nanowire) and/or tubular form.

In certain embodiments, the deposition layer may subsequently be separated from the substrate by any of a variety of suitable means (e.g., lift-off processes, etching, and/or photofabrication techniques such as UV-curable adhesives).

In certain embodiments, the III-nitride material layer may be used in a variety of suitable semiconductor devices including, for example, photonic devices, optoelectronic devices, high speed electronic devices, photovoltaic devices, light-emitting devices (e.g., light-emitting diodes or LEDs), and the like.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A deposition method, comprising:
providing a Group-III precursor;
providing a first Cl-based precursor in the presence of the Group-III precursor to produce a first intermediate species;
providing a second Cl-based precursor in the presence of the first intermediate species to produce a second intermediate species;
providing a N-based precursor in the presence of the second intermediate species to produce a product; and
depositing a layer comprising a III-nitride material onto a surface of a substrate.

2. The method of claim 1, wherein the Group-III precursor comprises indium, gallium, aluminum, trimethylindium, trimethylgallium, triethylgallium, trimethylaluminum, and/or mixtures thereof.

3. The method of claim 1, wherein the first Cl-based precursor comprises Cl₂, HCl, and/or mixtures thereof.

4. The method of claim 1, wherein the first intermediate species comprises a Group-III monochloride.

5. The method of claim 4, wherein the Group-III monochloride comprises InCl, GaCl, AlCl, dimers thereof, and/or mixtures thereof.

6. The method of claim 1, wherein the second Cl-based precursor comprises Cl₂, HCl, and/or mixtures thereof.

7. The method of claim 1, wherein the first Cl-based precursor and the second Cl-based precursor are the same.

8. The method of claim 1, wherein the first Cl-based precursor and the second Cl-based precursor are different.

9. The method of claim 1, wherein the second intermediate species comprises a Group-III trichloride.

10. The method of claim 9, wherein the Group-III trichloride comprises InCl₃, GaCl₃, AlCl₃, dimers thereof, and/or mixtures thereof.

11. The method of claim 1, wherein the N-based precursor comprises NH₃.

12. The method of claim 1, wherein the product comprises a Group-III amidodichloride.

13. The method of claim 12, wherein the Group-III amidodichloride comprises Cl₂InNH₂, Cl₂GaNH₂, Cl₂AlNH₂, mixtures thereof, and/or oligomers thereof.

14. The method of claim 12, wherein the Group-III amidodichloride readily reacts to produce a III-nitride material.

15. The method of claim 1, wherein the III-nitride material comprises GaN.

16. The method of claim 1, wherein the III-nitride material comprises AlN.

17. The method of claim 1, wherein the III-nitride material comprises InN.

18. The method of claim 1, wherein the III-nitride material comprises AlGaN.

19. The method of claim 1, wherein the III-nitride material comprises InGaN.

20. The method of claim 1, wherein the layer comprises an epitaxial layer.

21. The method of claim 1, wherein the deposition method is chemical vapor deposition.

22. The method of claim 1, wherein the deposition method is metal organic chemical vapor deposition.
